(19) United States
(12) Patent Application Publication
(10) Pub. No.: US 2026/0090456 A1
(43) Pub. Date: Mar. 26, 2026

(54) SEMICONDUCTOR PACKAGE WITH MOLDING LAYER AND PROTECTIVE LAYER

(71) Applicant: SAMSUNG ELECTRONICS CO., LTD., Suwon-si (KR)

(72) Inventor: Minjung KIM, Suwon-si (KR)

(73) Assignee: SAMSUNG ELECTRONICS CO., LTD., Suwon-si (KR)

(21) Appl. No.: 19/082,576

(22) Filed: Mar. 18, 2025

(30) Foreign Application Priority Data
Sep. 24, 2024 (KR) 10-2024-0129179

(51) Int. Cl. H01L 23/29; H01L 23/31; H01L 23/373; H01L 23/498

(52) U.S. Cl. CPC H10W 74/473; H10W 40/257; H10W 74/121; H10W 90/701

(57) ABSTRACT

A semiconductor package includes: a package substrate; a semiconductor chip on the package substrate; a molding layer on the semiconductor chip on the package substrate; a protective layer on a first surface of the molding layer; and one or more connection terminals on a surface of the package substrate, in which an elastic modulus of the protective layer is larger than an elastic modulus of the molding layer.

### CROSS-REFERENCE TO RELATED APPLICATIONS

This U.S. non-provisional patent application claims priority under 35 U.S.C. § 119 of Korean Patent Application No. 10-2024-0129179, filed on Sep. 24, 2024, the entire contents of which are hereby incorporated by reference.

### BACKGROUND

The present disclosure herein relates to a semiconductor package with a molding layer and a protective layer.

A semiconductor package and a semiconductor module incorporate an integrated circuit chip in a form suitable for use in electronic products. A semiconductor module includes a semiconductor package and a wiring substrate on which the semiconductor module is mounted. In general, in a semiconductor package, a semiconductor chip is mounted on a substrate, and the semiconductor chip and the substrate are electrically connected to each other using bonding wires or bumps, and a molding layer is provided on the substrate to protect the semiconductor chip. With the development of semiconductor technology, semiconductor chips are reduced in size. On the contrary, various functions are integrated in a single semiconductor chip. Therefore, in semiconductor packages, heat may be generated from semiconductor chips or semiconductor package warpage or the like may occur.

### SUMMARY

The present disclosure provides a semiconductor package with improved structural stability.

The present disclosure also provides a semiconductor package with improved heat dissipation characteristics.

The purposes of the present disclosure are not limited to the above-mentioned purposes, and other purposes not mentioned would be clearly understood by those skilled in the art from the disclosure below.

According to an aspect of the disclosure, a semiconductor package includes: a package substrate; a semiconductor chip on the package substrate; a molding layer on the semiconductor chip on the package substrate; a protective layer on a first surface of the molding layer; and one or more connection terminals on a surface of the package substrate, in which an elastic modulus of the protective layer is larger than an elastic modulus of the molding layer.

According to an aspect of the disclosure, a semiconductor package includes: a package substrate; a semiconductor chip on the package substrate; a first molding layer on the semiconductor chip on the package substrate; a second molding layer on a first surface of the first molding layer; and one or more external terminals provided on a surface of the package substrate, in which the semiconductor chip is vertically spaced apart from the second molding layer, in which a thermal conductivity of the first molding layer is higher than a thermal conductivity of the second molding layer, and in which a thickness of the second molding layer is less than a thickness of the first molding layer.

According to an aspect of the disclosure, a semiconductor package includes: a package substrate; a semiconductor chip on the package substrate; a molding layer on the semiconductor chip on the package substrate; a protective layer on a surface of the molding layer; and one or more connection terminals provided on a surface of the package substrate, in which the molding layer includes one or more thermal conductive members dispersed in the molding layer, in which a thickness of the protective layer is less than a thickness of the molding layer, and in which the protective layer includes: an insulating layer formed of a molding member, and at least one of a metal layer, a metal nitride layer, or a ceramic layer stacked on the insulating layer.

### BRIEF DESCRIPTION OF DRAWINGS

The accompanying drawings are included to provide a further understanding of the embodiments of the present disclosure, and are incorporated in and constitute a part of this specification. The drawings illustrate embodiments of the embodiments of the present disclosure and, together with the description, serve to explain principles of the embodiments of the present disclosure. In the drawings:

FIG. 1 is a cross-sectional view for describing a semiconductor package according to embodiments of the present disclosure;

FIGS. 2 to 4 are enlarged views of region A of FIG. 1;

FIGS. 5 to 11 are cross-sectional views for describing a semiconductor package according to embodiments of the present disclosure; and

FIGS. 12 to 23 are cross-sectional views illustrating a method for manufacturing a semiconductor package according to embodiments of the present disclosure.

### DETAILED DESCRIPTION

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

A semiconductor package according to the embodiments of the present disclosure will be described with reference to the drawings.

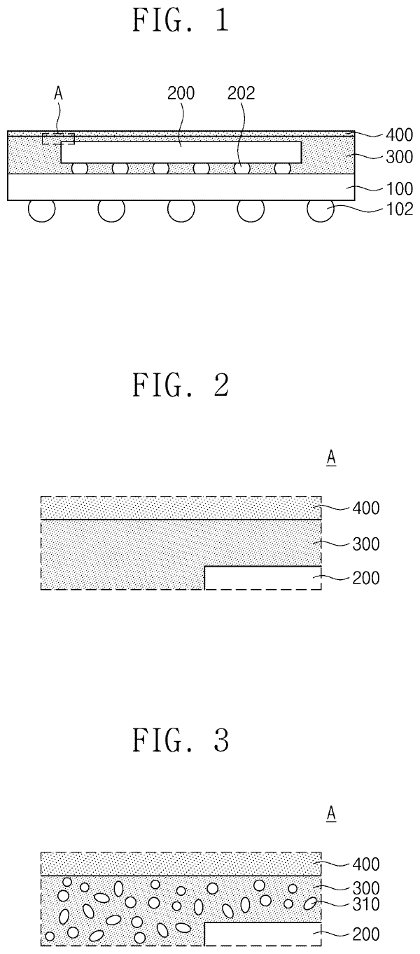

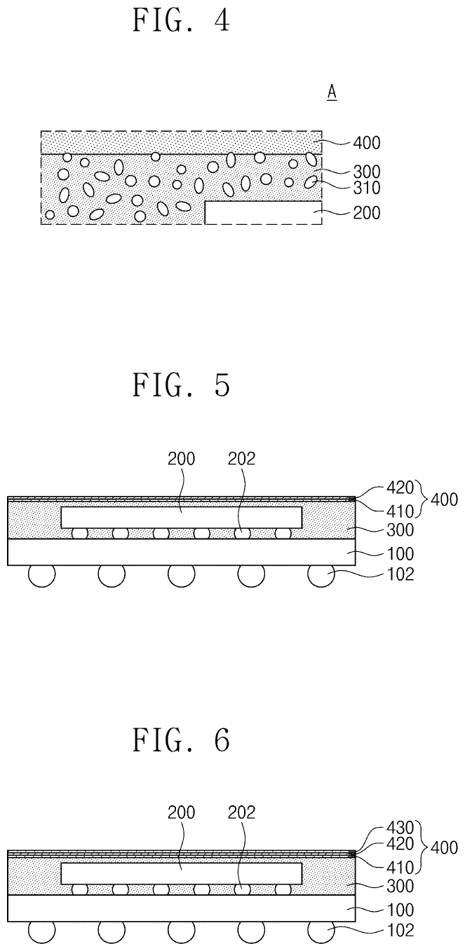

FIG. 1 is a cross-sectional view for describing a semiconductor package according to embodiments of the embodiments of the present disclosure. FIGS. 2 and 4 are enlarged views of region A of FIG. 1.

Referring to FIGS. 1 and 2, a package substrate 100 may be provided. The package substrate 100 may be a substrate for mounting a semiconductor package on an external device, a mother board, or another substrate. In one or more examples, the package substrate 100 may be an interposer for redistributing semiconductor chips of a semiconductor package and connecting the semiconductor chips to a package substrate of the semiconductor package. In one or more examples, an interposer may be an electrical interface routing between one socket or connection to another. The purpose of an interposer may be to spread a connection to a wider pitch or reroute a connection to a different connection. The package substrate 100 may be a printed circuit board (PCB) with a signal pattern provided on an upper surface of the package substrate 100. The signal pattern may include upper substrate pads. In one or more examples, the package substrate 100 may be a redistribution substrate with a plurality of wiring layers.

External terminals 102 may be arranged under the package substrate 100. In detail, the external terminal 102 may be arranged on lower substrate pads arranged on a lower surface of the package substrate 100. The external terminals 102 may include a solder ball or solder bump, and the semiconductor package may be provided in a form of a ball grid array (BGA), a fine ball-grid array (FBGA), or a land grid array (LGA) according to a type and arrangement of the external terminals 102. However, as understood by one of ordinary skill in the art, the external terminals 102 are not limited to these configurations and may include any suitable shape known to one of ordinary skill in the art.

A semiconductor chip 200 may be disposed on the package substrate 100. The semiconductor chip 200 may be a logic chip or memory chip. However, the embodiments of the present disclosure are not limited thereto, and the semiconductor chip 200 may include a semiconductor chip or passive device including a logic chip, a memory chip, and other various integrated devices. A lower surface of the semiconductor chip 200 may be an active surface (e.g., containing one or more electronic components), and an upper surface of the semiconductor chip 200 may be an inactive surface. For example, the semiconductor chip 200 may be disposed face-down on the package substrate 100.

The semiconductor chip 200 may be mounted on the package substrate 100. For example, the semiconductor chip 200 may be mounted on the package substrate 100 in a flip chip manner (e.g., method for interconnecting dies to external circuitry with solder bumps that have been deposited onto chip pads). In one or more examples, the semiconductor chip 200 may be electrically connected to the package substrate 100 through chip connection terminals 202. The chip connection terminals 202 may be provided between chip pads of the semiconductor chip 200 and the upper substrate pads of the package substrate 100.

Although FIG. 1 illustrates that the semiconductor chip 200 is mounted on the package substrate 100 in a flip chip manner, the embodiments of the present disclosure are not limited thereto. The semiconductor chip 200 may be mounted on the package substrate 100 in a wire bonding manner or the like as necessary. For example, the semiconductor chip 200 may be disposed face-up on the package substrate 100. In one or more examples, the lower surface of the semiconductor chip 200 may be attached to the upper surface of the package substrate 100 using an adhesive layer in lieu of the chip connection terminals 202. A bonding wire may be connected chip pads provided on the upper surface of the semiconductor chip 200 and the upper substrate pads of the package substrate 100.

Although FIG. 1 illustrates that the single semiconductor chip 200 is provided on the package substrate 100, the embodiments of the present disclosure are not limited thereto. Two or more semiconductor chips 200 may be provided on the package substrate 100. For example, the semiconductor chips 200 may be horizontally spaced apart from each other. In one or more examples, the semiconductor chips 200 may be vertically stacked on the package substrate 100. Hereinafter, descriptions will be continuously provided with respect to the embodiment of FIG. 1.

In one or more examples, an under-fill layer may be disposed between the package substrate 100 and the semiconductor chip 200. The under-fill layer may fill a space between the package substrate 100 and the semiconductor chip 200 and may surround the chip connection terminals 202.

A first molding layer 300 may be disposed on the package substrate 100. The first molding layer 300 may surround the semiconductor chip 200. The first molding layer 300 may cover the semiconductor chip 200 on the package substrate 100. In one or more examples, the first molding layer 300 may cover side surfaces and upper surface of the semiconductor chip 200. The side surfaces of the semiconductor chip 200 may be perpendicular to the upper surface of the semiconductor chip 200. In one or more examples, the upper surface of the semiconductor chip 200 may be exposed on an upper surface of the first molding layer 300. The upper surface of the semiconductor chip 200 and the upper surface of the first molding layer 300 may be substantially flat and coplanar with each other. The first molding layer 300 may include a first molding member. For example, the first molding member may include an insulating material. The first molding layer 300 may include an insulative polymer material such as an epoxy molding compound (EMC).

A second molding layer 400 may be disposed on the first molding layer 300. The second molding layer 400 may cover the upper surface of the first molding layer 300. The second molding layer 400 may be in contact with the upper surface of the first molding layer 300. The semiconductor chip 200 may be vertically spaced apart from the second molding layer 400. For example, a portion of the first molding layer 300 may be interposed between the upper surface of the semiconductor chip 200 and the second molding layer 400. Side surfaces of the second molding layer 400 may be aligned with side surfaces of the first molding layer 300. A thickness of the second molding layer 400 may be less than a thickness of the first molding layer 300. In one or more examples, the thicknesses of the first molding layer 300 and the second molding layer 400 may be measured in a vertical direction from the upper surface of the package substrate 100. For example, the thickness of the first molding layer 300 may be a distance from a lower surface, which is in contact with the upper surface of the package substrate 100, of the first molding layer 300 to an upper surface, facing the lower surface, of the first molding layer 300. For example, the thickness of the second molding layer 400 may be a distance from a lower surface, which is in contact with the upper surface of the first molding layer 300, of the second molding layer 400 to an upper surface, facing the lower surface, of the second molding layer 400. The thickness of the second molding layer 400 may be about 1 micrometer to about 500 micrometers. The second molding layer 400 may be a protective layer for preventing the first molding layer 300 from being damaged. An elastic modulus of the second molding layer 400 may be larger than an elastic modulus of the first molding layer 300. In one or more examples, the thermal conductivity of the first molding layer 300 may be higher than thermal conductivity of the second molding layer 400. As understood by one of ordinary skill in the art, thermal conductivity refers to the ability of a given material to conduct/transfer heat. It is generally denoted by the symbol ‘k’ but can also be denoted by ‘λ’ and ‘κ’. The reciprocal of this quantity is known as thermal resistivity. The second molding layer 400 may include a second molding member different from the first molding member. The second molding member may include an epoxy polymer material or polyimide (PI) polymer material. For example, the epoxy polymer material may include an epoxy molding compound (EMC).

According to one or more embodiments, since the first molding layer 300 having high thermal conductivity is provided on the semiconductor chip 200, heat generated from the semiconductor chip 200 may be efficiently dissipated. For example, a semiconductor package having improved heat dissipation efficiency may be provided. Furthermore, since the second molding layer 400 having a high elastic modulus is provided on the upper surface of the first molding layer 300, damage such as a crack or the like that may occur in the upper surface of the first molding layer 300 may be advantageously prevented. For example, a semiconductor package having improved structural stability may be provided. Furthermore, since the second molding layer 400 is thin, the second molding layer 400 may not hinder heat dissipation through the first molding layer 300.

According to other embodiments, the first molding layer 300 may further include pillars 310 as illustrated in FIG. 3. The pillars 310 may be provided in the first molding member constituting the first molding layer 300. The pillars 310 may be dispersed in the first molding member. The pillars 310 may have a shape of a bead, wire, or rod. The pillars 310 may be provided with a volume fraction of about 1% to about 50% with respect to a volume of the first molding layer 300. A width, a diameter, or a length of a major axis of the pillars 310 may be about 0.1 micrometers to about 30 micrometers. The pillars 310 may improve the thermal conductivity of the first molding layer 300. Accordingly, heat dissipation from the semiconductor chip 200 through the first molding layer 300 may be improved. The pillars 310 may include an insulative material. The pillars 310 may include a material having high thermal conductivity. For example, the pillars 310 may include aluminum oxide (Al₂O₃). In one or more examples, the pillars 310 may include at least one of silicon oxide such as amorphous silicon oxide (SiO₂) or crystalline silicon oxide (SiO₂), magnesium oxide (MgO), zinc oxide (ZnO), silicon carbide (SiC), aluminum nitride (AlN), beryllium oxide (BeO), or boron nitride (BN). In one or more examples, the pillars 310 may include any other insulative material known to one of ordinary skill in the art having high thermal conductivity. However, the embodiments of the present disclosure are not limited thereto, and the pillars 310 may include metal materials having high thermal conductivity.

According to one or more embodiments, since the first molding layer 300 includes the pillars 310 having high thermal conductivity, heat dissipation through the first molding layer 300 may be more efficiently performed.

In the case where the first molding layer 300 includes the pillars 310 inside the first molding layer 300, damage such as a crack or the like may occur in an interface between the molding member constituting the first molding layer 300 and the pillars 310. For example, when the first molding layer 300 contracts or expands due to heat, damage such as a crack or the like may occur due to the first molding layer 300.

According to one or more embodiments, since the second molding layer 400 having a high elastic modulus is provided on the upper surface of the first molding layer 300, damage to the first molding layer 300 may be suppressed by the second molding layer 400. For example, a semiconductor package having improved structural stability may be provided. As understood by one of ordinary skill in the art, an elastic modulus may refer to an object's or substance's resistance to being deformed elastically (e.g., non-permanently) when a stress is applied to it.

According to other embodiments, the first molding layer 300 may further include pillars 310 as illustrated in FIG. 4. At least a portion of the pillars 310 may protrude beyond an upper surface of the first molding layer 300.

The second molding layer 400 may be provided on the first molding layer 300. The second molding layer 400 may cover the upper surface of the first molding layer 300. The second molding layer 400 may cover the pillars 310 protruding beyond the upper surface of the first molding layer 300. For example, the second molding layer 400 may protect the first molding layer 300 so that the pillars 310 may not protrude to the outside. Accordingly, the structural stability of the semiconductor package may be improved. In the case where the thickness of the second molding layer 400 is less than about 1 micrometer, the second molding layer 400 may be damaged due to an external impact, and thus the first molding layer 300 and the pillars 310 may be exposed to the outside. In the case where the thickness of the second molding layer 400 is larger than about 500 micrometers, the semiconductor package may be excessively thick, and heat dissipation through the first molding layer 300 may be hindered by the second molding layer 400.

In the following embodiments, the same reference numerals are used for the components described above with respect to the embodiments of FIGS. 1 to 4, and descriptions thereof will be omitted or provided briefly for convenience. For example, differences between the following embodiments and the embodiments of FIGS. 1 to 4 will be focused on.

FIGS. 5 and 6 are cross-sectional views for describing a semiconductor package according to embodiments of the present disclosure.

Referring to FIG. 5, the semiconductor chip 200 may be mounted on the package substrate 100. The first molding layer 300 may cover the semiconductor chip 200 on an upper surface of the package substrate 100.

A protective layer 400 may be disposed on the first molding layer 300. The protective layer 400 may correspond to the second molding layer 400 described with reference to FIGS. 1 to 4. For example, the protective layer 400 may be a protective layer for preventing the first molding layer 300 from being damaged.

The protective layer 400 may be in contact with the upper surface of the first molding layer 300. The semiconductor chip 200 may be vertically spaced apart from the protective layer 400. For example, side surfaces of the protective layer 400 may be aligned with side surfaces of the first molding layer 300. A thickness of the protective layer 400 may be less than a thickness of the first molding layer 300. The thickness of the protective layer 400 may be about 1 micrometer to about 500 micrometers. An elastic modulus of the protective layer 400 may be larger than an elastic modulus of the first molding layer 300. Thermal conductivity of the first molding layer 300 may be higher than thermal conductivity of the protective layer 400.

The protective layer 400 may be a multi-layer structure provided as a plurality of material layers. For example, the protective layer 400 may include an insulating layer 410 and a support layer 420.

The insulating layer 410 may be in contact with the upper surface of the first molding layer 300. An elastic modulus of the insulating layer 410 may be larger than an elastic modulus of the first molding layer 300. Thermal conductivity of the first molding layer 300 may be higher than thermal conductivity of the insulating layer 410. The insulating layer 410 may include a different material from that of the first molding layer 300. The insulating layer 410 may include the same material as the second molding layer 400 described with reference to FIGS. 1 to 4. The insulating layer 410 may include an epoxy polymer material or polyimide (PI) polymer material. For example, the epoxy polymer material may include an epoxy molding compound (EMC).

The support layer 420 may be disposed on the insulating layer 410. The support layer 420 may be in contact with an upper surface of the insulating layer 410. A stiffness of the support layer 420 may be higher than stiffness of the insulating layer 410. For example, the support layer 420 may include a metal layer, a metal nitride layer, a ceramic layer, or a multi-layer structure thereof. The metal layer may include copper (Cu), titanium (Ti), or stainless steel. The metal nitride layer may include titanium nitride (TiN). The ceramic layer may include silicon nitride (SiN) ceramic.

According to embodiments of the present disclosure, the insulating layer 410 having a higher elastic modulus than the first molding layer 300 may be provided on a surface of the first molding layer 300. Therefore, the insulating layer 410 may suppress damage that may occur in the surface of the first molding layer 300. Furthermore, the support layer 420 having higher stiffness than the insulating layer 410 may be provided on a surface of the insulating layer 410. Therefore, the support layer 420 may suppress deformation of the insulating layer 410, and thus, the insulating layer 410 may more efficiently suppress damage that may occur in the surface of the first molding layer 300.

According to other embodiments, the protective layer 400 may be a multi-layer structure provided as a plurality of material layers. For example, the protective layer 400 may include a first insulating layer 410, a support layer 420, and a second insulating layer 430. The first insulating layer 410 may correspond to the insulating layer 410 described with reference to FIG. 5. The support layer 420 may correspond to the support layer 420 described with reference to FIG. 5.

The second insulating layer 430 may be disposed on the support layer 420. The second insulating layer 430 may be in contact with an upper surface of the support layer 420. An elastic modulus of the second insulating layer 430 may be equal to or larger than an elastic modulus of the first molding layer 300. The second insulating layer 430 may include the same material as the first insulating layer 410. The second insulating layer 430 may include an epoxy polymer material or polyimide (PI) polymer material. For example, the epoxy polymer material may include an epoxy molding compound (EMC).

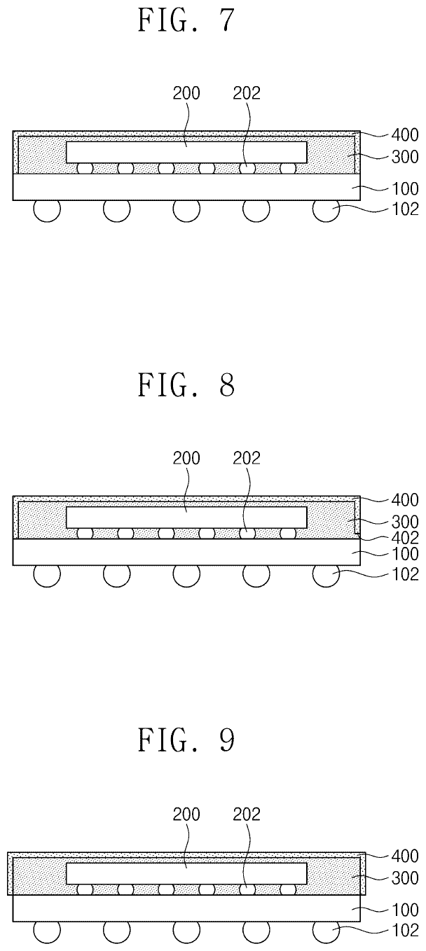

FIGS. 7 to 10 are cross-sectional views for describing a semiconductor package according to embodiments of the present disclosure.

Referring to FIG. 7, the semiconductor chip 200 may be mounted on the package substrate 100. The first molding layer 300 may cover the semiconductor chip 200 on an upper surface of the package substrate 100.

A second molding layer 400 may be disposed on the first molding layer 300. The second molding layer 400 may cover the upper surface of the first molding layer 300. The second molding layer 400 may be in contact with the upper surface of the first molding layer 300. The second molding layer 400 may extend from the upper surface of the first molding layer 300 to side surfaces of the first molding layer 300. The second molding layer 400 may cover the side surfaces of the first molding layer 300. The second molding layer 400 may be in contact with the side surfaces of the first molding layer 300. The second molding layer 400 may be in contact with an upper surface of the package substrate 100 on the side surfaces of the first molding layer 300. For example, the first molding layer 300 may be completely surrounded by the package substrate 100 and the second molding layer 400. Side surfaces of the second molding layer 400 may be aligned with side surfaces of the package substrate 100.

A thickness of the second molding layer 400 may be less than a thickness of the first molding layer 300. In one or more examples, the thicknesses of the second molding layer 400 may be measured in a direction perpendicular to a surface of the first molding layer 300. For example, the thickness of the second molding layer 400 on the upper surface of the first molding layer 300 may be a distance from the upper surface of the first molding layer 300 to an upper surface of the second molding layer 400. For example, the thickness of the second molding layer 400 on the side surfaces of the first molding layer 300 may be a distance from the side surfaces of the first molding layer 300 to the side surfaces of the second molding layer 400.

According to other embodiments, the second molding layer 400 may have at least one hole 402 as illustrated in FIG. 8. The hole 402 may be disposed in at least one of the side surfaces of the second molding layer 400. The hole 402 may penetrate the second molding layer 400 and expose the first molding layer 300. The hole 402 may be filled with a portion of the first molding layer 300. For example, the portion of the first molding layer 300 may penetrate the second molding layer 400 and may be exposed on one of the side surfaces of the second molding layer 400.

Although FIG. 8 illustrates that the hole 402 is disposed in one of the side surfaces of the second molding layer 400, the embodiments of the present disclosure are not limited thereto. The hole 402 may be disposed in the upper surface of the second molding layer 400. The hole 402 may vertically penetrate the second molding layer 400 and expose the upper surface of the first molding layer 300. In one or more examples, a first hole may be on an upper surface of the second molding layer 400, and a second hole may be on the side surface of the second molding layer 400. In one or more examples, a plurality of holes may be located on the side surfaces of the second molding layer 400 and/or on the upper surface of the second molding layer 400.

According to other embodiments, side surfaces of the first molding layer 300 may be vertically aligned with side surfaces of the package substrate 100 as illustrated in FIG. 9. The second molding layer 400 may cover the upper surface and side surfaces of the first molding layer 300. Therefore, the second molding layer 400 may protrude beyond the side surfaces of the package substrate 100.

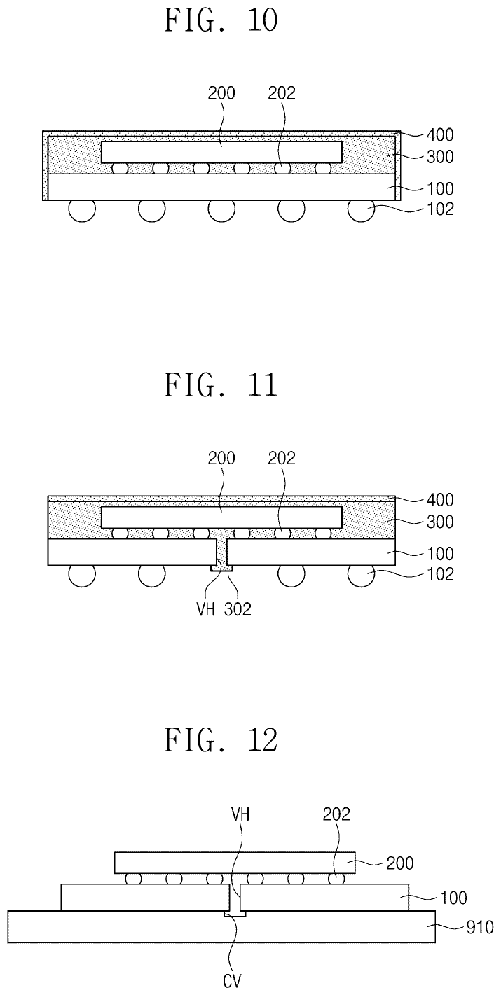

According to other embodiments, side surfaces of the first molding layer 300 may be vertically aligned with side surfaces of the package substrate 100 as illustrated in FIG. 10. The second molding layer 400 may cover the upper surface and side surfaces of the first molding layer 300. The second molding layer 400 may extend onto the side surfaces of the package substrate 100. The second molding layer 400 may cover the side surfaces of the package substrate 100. The second molding layer 400 may be in contact with the side surfaces of the package substrate 100. As illustrated in FIG. 10, the side surfaces of the package substrate 100 and the side surfaces of the first molding layer 300 are aligned with each other.

FIG. 11 is a cross-sectional view for describing a semiconductor package according to embodiments of the present disclosure.

Referring to FIG. 11, the package substrate 100 may have at least one vent hole VH. The vent hole VH may vertically penetrate the package substrate 100. For example, the vent hole VH may connect an upper surface and lower surface of the package substrate 100. The vent hole VH may be located under the semiconductor chip 200.

A first molding layer 300 may be disposed on the package substrate 100. The first molding layer 300 may surround the semiconductor chip 200. The first molding layer 300 may cover the semiconductor chip 200 on the package substrate 100. The first molding layer 300 may fill a space between the package substrate 100 and the semiconductor chip 200.

A portion 302 of the first molding layer 300 may extend onto the lower surface of the package substrate 100 along the vent hole VH. The portion 302 of the first molding layer 300 may protrude beyond the lower surface of the package substrate 100. The portion 302 of the first molding layer 300 may be spaced apart from the external terminals 102. A lower end of the portion 302 of the first molding layer 300 may be located at a higher vertical level than lower ends of the external terminals 102. For example, a distance from the lower surface of the package substrate 100 to the lower end of the portion 302 of the first molding layer 300 may be less than a distance from the lower surface of the package substrate 100 to the lower ends of the external terminals 102. As understood by one of ordinary skill in the art, the embodiments are not limited to the configuration illustrated in FIG. 11. For example, the package substrate 100 may include a vent hole on a side surface of the package substrate 100. In one or more examples, the package substrate 100 may include a plurality of vent holes. The plurality of vent holes may be included on the lower surface of the package substrate 100 or the side surface of the package substrate. In one or more examples, the lower surface of the package substrate 100 may include one or more vent holes on the lower surface of the package substrate 100 and one or more vent holes on the side surfaces of the package substrate 100.

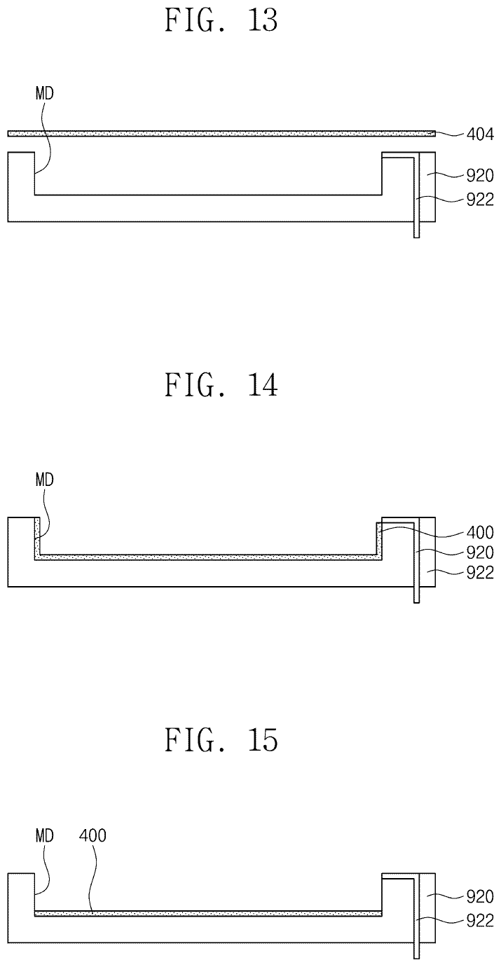

FIGS. 12 to 17 are cross-sectional views illustrating a method for manufacturing a semiconductor package according to embodiments of the present disclosure.

Referring to FIG. 12, a first carrier substrate 910 may be provided. The first carrier substrate 910 may be an insulating substrate including glass or polymer or a conductive substrate including metal.

The first carrier substrate 910 may have a cavity CV. The cavity CV may be provided in an upper surface of the first carrier substrate 910. The cavity CV may have a shape recessed inward from the upper surface of the first carrier substrate 910.

The package substrate 100 may be attached onto the first carrier substrate 910. In more detail, an adhesive layer may be provided on a lower surface of the package substrate 100. The package substrate 100 may be attached to the first carrier substrate 910 using the adhesive layer. The package substrate 100 may have at least one vent hole VH. The vent hole VH may vertically penetrate the package substrate 100. The vent hole VH may be aligned with the cavity CV of the first carrier substrate 910. For example, the cavity CV may communicate with the vent hole VH. The cavity CV may be connected to the outside through the vent hole VH.

The semiconductor chip 200 may be mounted on the package substrate 100. For example, the chip connection terminals 202 may be provided on chip pads of the semiconductor chip 200. The semiconductor chip 200 may be disposed on the package substrate 100 so that the chip connection terminals 202 may be aligned with upper substrate pads of the package substrate 100. Thereafter, the chip connection terminals 202 may be coupled to the upper substrate pads and the chip pads by performing a reflow process.

Referring to FIG. 13, a first mold tool 920 may be provided. The first mold tool 920 may be a mold frame for forming the first molding layer 300 of the semiconductor package. The first mold tool 920 may have an internal region MD. The internal region MD may have a shape recessed inward from an upper surface of the first mold tool 920. However, is the embodiments of the present disclosure are not limited thereto, and the internal region MD may be provided in various forms according to a shape of the first molding layer 300 to be formed.

The first mold tool 920 may have a mold injection hole 922. The mold injection hole 922 may be for injecting a mold member from the outside of the first mold tool 920 into the internal region MD. The mold injection hole 922 may be disposed on an inner wall of the internal region MD. Although FIG. 13 illustrates that the mold injection hole 922 is connected on the inner wall of the internal region MD, the embodiments of the present disclosure are not limited thereto. According to other embodiments, the mold injection hole 922 may be connected on a bottom surface of the internal region MD.

A preliminary protective layer 404 may be provided. The preliminary protective layer 404 may be a preliminary material for forming the second molding layer 400 or the protective layer 400. The preliminary protective layer 404 may be an insulating layer. In one or more examples, the preliminary protective layer 404 may include a multi-layer structure of at least one of a metal layer, a metal nitride layer, or a ceramic layer and the insulating layer. The insulating layer may include a second molding member. The second molding member may include an epoxy polymer material or polyimide (PI) polymer material. The metal layer may include copper (Cu), titanium (Ti), or stainless steel. The metal nitride layer may include titanium nitride (TiN). The ceramic layer may include silicon nitride (SiN) ceramic.

The preliminary protective layer 404 may be disposed on the first mold tool 920. The preliminary protective layer 404 may be disposed so that the insulating layer covers the internal region MD of the first mold tool 920.

Referring to FIG. 14, the second molding layer 400 may be formed by performing a first process on the preliminary protective layer 404. For example, the first process may include a transfer mold process. In more detail, the preliminary protective layer 404 may be provided on the first mold tool 920. The preliminary protective layer 404 may be pressed from above to mold the preliminary protective layer 404 into the second molding layer 400. A pressure process for the preliminary protective layer 404 may be performed using a press mold or any other suitable pressure process known to one of ordinary skill in the art. The second molding layer 400 may be formed to cover the bottom surface and the inner walls of the internal region MD of the first mold tool 920. The second molding layer 400 may not cover the mold injection hole 922 in the internal region MD. In the case where the second molding layer 400 is formed to cover the mold injection hole 922, a portion of the second molding layer 400 covering the mold injection hole 922 may be removed through an additional process.

Heat may be applied to the preliminary protective layer 404 during the first process to more easily mold the preliminary protective layer 404. For example, a heating process may be performed at a higher temperature than a glass transition temperature of the preliminary protective layer 404. The heating process may be performed at a lower temperature than a melting point of the preliminary protective layer 404. The preliminary protective layer 404 may transition to a rubbery state through the heating process. The glass transition temperature of the preliminary protective layer 404 may be higher than about 140 degrees.

As necessary, the second molding layer 400 may be cured after the second molding layer 400 is formed through the first process. The curing process may include a thermal curing process or a photocuring process.

Referring to FIG. 15, according to other embodiments, a portion of the second molding layer 400 may be removed. In more detail, a portion of the second molding layer 400 located on the inner walls of the internal region MD of the first mold tool 920 may be removed. The second molding layer 400 may cover the bottom surface of the internal region MD. The second molding layer 400 may expose the inner walls of the internal region MD. Hereinafter, descriptions will be continuously provided with respect to the embodiment of FIG. 14.

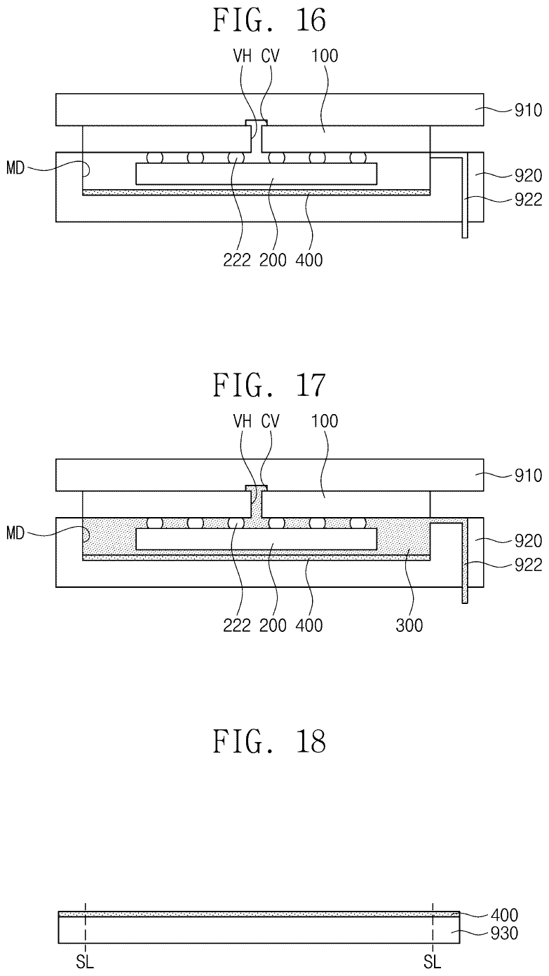

Referring to FIG. 16, the first carrier substrate 910 may be disposed on the first mold tool 920. Here, the first carrier substrate 910 may be provided so that the semiconductor chip 200 is located in the internal region MD of the first mold tool 920. For example, the resultant structure of FIG. 12 may be turned upside down so that the package substrate 100 and the semiconductor chip 200 may be located under the first carrier substrate 910. The package substrate 100 may not be inserted into the internal region MD. The package substrate 100 may cover the internal region MD. Accordingly, the internal region MD may be sealed by the first mold tool 920 and the package substrate 100, and the semiconductor chip 200 may be located in the internal region MD.

According to other embodiments, the package substrate 100 may be inserted into the internal region MD. In this case, the first carrier substrate 910 may be in contact with an upper end of the first mold tool 920. The first carrier substrate 910 may cover the internal region MD. Accordingly, the internal region MD may be sealed by the first mold tool 920 and the first carrier substrate 910. In this case, a location of the mold injection hole 922 may be different from that illustrated in FIG. 16. The mold injection hole 922 may be provided in the inner walls or bottom surface of the internal region MD, wherein the mold injection hole 922 may not be covered with the package substrate 100 on the inner walls or bottom surface of the internal region MD.

Referring to FIG. 17, a first mold member may be injected into the internal region MD. The first mold member may be injected into the internal region MD through the mold injection hole 922. The first mold member may fill the internal region MD. In more detail, the first mold member may cover the semiconductor chip 200 on a lower surface of the package substrate 100. The first mold member may fill a space between the package substrate 100 and the second molding layer 400. The first mold member may flow between the package substrate 100 and the semiconductor chip 200. The first mold member may be discharged from a space between the package substrate 100 and the semiconductor chip 200 to the cavity CV of the first carrier substrate 910 via the vent hole VH.

The first molding layer 300 may be formed by curing the first mold member. The curing process may include a thermal curing process or a photocuring process.

Thereafter, the semiconductor package may be removed from the first mold tool 920. The first carrier substrate 910 may be removed. The external terminals 102 may be attached to a lower surface of the package substrate 100.

FIGS. 18 to 20 are cross-sectional views illustrating a method for manufacturing a semiconductor package according to embodiments of the present disclosure.

Referring to FIG. 18, a second carrier substrate 930 may be provided. The second carrier substrate 930 may be an insulating substrate including glass or polymer or a conductive substrate including metal.

The second molding layer 400 may be formed on the second carrier substrate 930. For example, after applying a second molding member on the second carrier substrate 930, the second molding layer 400 may be formed by curing the second molding member. An application process of the second molding member may include spin coating or any other suitable application process known to one of ordinary skill in the art. The curing process may include a thermal curing process or a photocuring process. In one or more examples, the second molding layer 400 may be provided as a film-type mold film. For example, the mold film may be attached onto the second carrier substrate 930 to form the second molding layer 400.

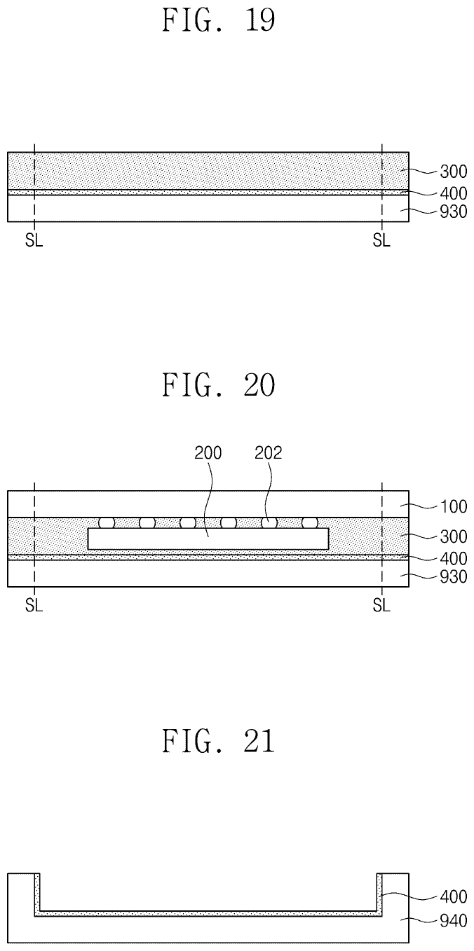

Referring to FIG. 19, the first molding layer 300 may be formed on the second molding layer 400. For example, a material layer including the first molding member may be disposed on the second molding layer 400. Heat may be applied to the material layer. A heating process may be performed at a higher temperature than a glass transition temperature of the material layer. The heating process may be performed at a lower temperature than a melting point of the material layer. The material layer may transition to a rubbery state through the heating process. Accordingly, the first molding layer 300 covering an upper surface of the second molding layer 400 may be formed.

In one or more examples, the first molding layer 300 may be provided as a film-type mold film. For example, the mold film may be attached onto the second molding layer 400 to form the first molding layer 300.

Referring to FIG. 20, a resultant structure that is the same as or similar to that described with reference to FIG. 12 may be provided. For example, the semiconductor chip 200 may be mounted on the package substrate 100. In one or more examples, the package substrate 100 may not be provided with the vent hole VH (see FIG. 12).

The package substrate 100 may be disposed on the second molding layer 400. In one or more examples, the resultant structure of FIG. 12 may be turned upside down so that the semiconductor chip 200 may be located under the package substrate 100.

The package substrate 100 may be moved down so that the semiconductor chip 200 may be inserted into the second molding layer 400. In one or more examples, the second molding layer 400 may be in a rubbery state. For example, the second molding layer 400 may be continuously heated at a temperature equal to or higher than the glass transition temperature of the second molding layer 400.

The package substrate 100 may be continuously moved down so that the semiconductor chip 200 may be buried in the second molding layer 400. The second molding layer 400 may be in contact with a lower surface of the package substrate 100. The heating process may be stopped, and the second molding layer 400 may be cured.

Thereafter, the package substrate 100, the first molding layer 300, and the second molding layer 400 may be cut along a sawing line SL so that the semiconductor package may be provided.

The second carrier substrate 930 may be removed. The external terminals 102 may be attached to one surface of the package substrate 100.

FIGS. 21 to 23 are cross-sectional views illustrating a method for manufacturing a semiconductor package according to embodiments of the inventive concept.

Referring to FIG. 21, a second mold tool 940 may be provided. The second mold tool 940 may be a mold frame for forming the first molding layer 300 and the second molding layer 400 of the semiconductor package. The second mold tool 940 may have an internal region. The internal region may have a shape recessed inward from an upper surface of the second mold tool 940. However, the embodiments of the present disclosure are not limited thereto, and the internal region may be provided in various forms according to shapes of the first molding layer 300 and the second molding layer 400 to be formed.

The second molding layer 400 may be formed in the second mold tool 940. A process of forming the second molding layer 400 may be the same as or similar to that described with reference to FIGS. 13 and 14. For example, a preliminary protective layer may be provided on the second mold tool 940. The preliminary protective layer may be an insulating layer. In one or more examples, the preliminary protective layer may include a multi-layer structure of at least one of a metal layer, a metal nitride layer, or a ceramic layer and the insulating layer. The preliminary protective layer may be disposed on the second mold tool 940. The preliminary protective layer may be disposed so that the insulating layer may cover the internal region of the second mold tool 940. The second molding layer 400 may be formed by performing a second process on the preliminary protective layer. For example, the second process may include a transfer mold process. The second molding layer 400 may be formed to cover the bottom surface and inner walls of the internal region of the second mold tool 940.

Heat may be applied to the preliminary protective layer during the second process to more easily form the second molding layer 400.

As necessary, the second molding layer 400 may be cured after the second molding layer 400 is formed through the second process.

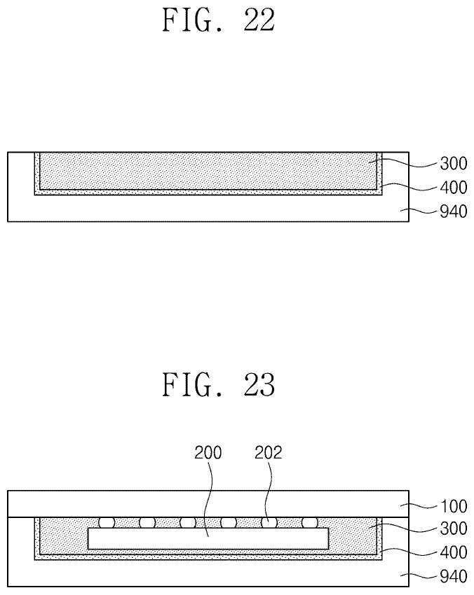

Referring to FIG. 22, the first molding layer 300 may be formed on the second molding layer 400. For example, a material layer including the first molding member may be disposed on the second molding layer 400. Heat may be applied to the material layer. A heating process may be performed at a higher temperature than a glass transition temperature of the material layer. The heating process may be performed at a lower temperature than a melting point of the material layer. The material layer may transition to a rubbery state through the heating process. Accordingly, the first molding layer 300 filling the internal region may be formed on the second molding layer 400.

Referring to FIG. 23, a resultant structure that is the same as or similar to that described with reference to FIG. 12 may be provided. For example, the semiconductor chip 200 may be mounted on the package substrate 100. In one or more examples, the package substrate 100 may not be provided with the vent hole VH (see FIG. 12).

The package substrate 100 may be disposed on the second molding layer 400. Here, the resultant structure of FIG. 12 may be turned upside down so that the semiconductor chip 200 may be located under the package substrate 100.

The package substrate 100 may be moved down so that the semiconductor chip 200 may be inserted into the second molding layer 400. Here, the second molding layer 400 may be in a rubbery state. For example, the second molding layer 400 may be continuously being heated at a temperature equal to or higher than the glass transition temperature of the second molding layer 400.

The package substrate 100 may be continuously moved down so that the semiconductor chip 200 may be buried in the second molding layer 400. The second molding layer 400 may be in contact with a lower surface of the package substrate 100. The package substrate 100 may be in contact with an upper end of the second mold tool 940. The heating process may be stopped, and the second molding layer 400 may be cured.

In a semiconductor package according to embodiments of the present disclosure, since a first molding layer having high thermal conductivity is provided on a semiconductor chip, heat generated from the semiconductor chip may be efficiently dissipated. For example, a semiconductor package having improved heat dissipation efficiency may be provided. Furthermore, since a second molding layer having a high elastic modulus is provided on the upper surface of the first molding layer, damage such as a crack or the like that may occur in the upper surface of the first molding layer may be prevented. For example, a semiconductor package having improved structural stability may be provided. Furthermore, since the second molding layer is thin, the second molding layer may not hinder heat dissipation through the first molding layer.

Moreover, since the first molding layer includes pillars having high thermal conductivity, heat dissipation through the first molding layer may be more efficiently performed. In addition, since the second molding layer having a high elastic modulus is provided on the upper surface of the first molding layer, damage to the first molding layer may be suppressed by the second molding layer. For example, a semiconductor package having improved structural stability may be provided. The second molding layer may protect the first molding layer so that the pillars may not protrude to the outside. Accordingly, the structural stability of the semiconductor package may be improved.

Furthermore, an insulating layer having a larger elastic modulus than the first molding layer may be provided on a surface of the first molding layer. Therefore, the insulating layer may suppress damage that may occur in the surface of the first molding layer. Furthermore, a support layer having higher stiffness than the insulating layer may be provided on a surface of the insulating layer. Therefore, the support layer may suppress deformation of the insulating layer, and thus the insulating layer may more efficiently suppress damage that may occur in the surface of the first molding layer.

Although embodiments of the present disclosure have been described with reference to the accompanying drawings, those of ordinary skill in the art could easily understood that the present disclosure can be carried out in other specific forms without changing the technical concept or essential features. Therefore, the above embodiments should be considered illustrative and should not be construed as limiting.

What is claimed is:

1. A semiconductor package comprising:
a package substrate;
a semiconductor chip on the package substrate;
a molding layer on the semiconductor chip on the package substrate;
a protective layer on a first surface of the molding layer; and
one or more connection terminals on a surface of the package substrate,
wherein an elastic modulus of the protective layer is larger than an elastic modulus of the molding layer.

2. The semiconductor package of claim 1, wherein a thermal conductivity of the molding layer is higher than a thermal conductivity of the protective layer.

3. The semiconductor package of claim 1, wherein the molding layer comprises:
a first molding member, and one or more pillars dispersed in the first molding member.

4. The semiconductor package of claim 3, wherein the one or more pillars comprise aluminum oxide (Al₂O₃).

5. The semiconductor package of claim 1, wherein the protective layer comprises:
an insulating layer formed of a second molding member, or
a multi-layer structure comprising at least one of a metal layer, a metal nitride layer, or a ceramic layer and the insulating layer formed of the second molding member.

6. The semiconductor package of claim 5, wherein the insulating layer is in contact with the molding layer.

7. The semiconductor package of claim 5, wherein an elastic modulus of the insulating layer is larger than the elastic modulus of the molding layer.

8. The semiconductor package of claim 7, wherein the insulating layer comprises an epoxy polymer material or polyimide (PI) polymer material.

9. The semiconductor package of claim 5,
wherein the metal layer comprises copper (Cu), titanium (Ti), or stainless steel,
the metal nitride layer includes titanium nitride (TiN), and
the ceramic layer includes silicon nitride (SiN).

10. The semiconductor package of claim 1, wherein a thickness of the protective layer is about 1 micrometer to about 500 micrometers.

11. The semiconductor package of claim 1, wherein the protective layer extends onto second surfaces of the molding layer and is provided on the second surfaces of the molding layer, wherein the second surfaces of the molding layer are perpendicular to the first surface of the molding layer.

12. A semiconductor package comprising:
a package substrate;
a semiconductor chip on the package substrate;
a first molding layer on the semiconductor chip on the package substrate;
a second molding layer on a first surface of the first molding layer; and
one or more external terminals provided on a surface of the package substrate,
wherein the semiconductor chip is vertically spaced apart from the second molding layer,
wherein a thermal conductivity of the first molding layer is higher than a thermal conductivity of the second molding layer, and
wherein a thickness of the second molding layer is less than a thickness of the first molding layer.

13. The semiconductor package of claim 12, wherein the first molding layer comprises one or more pillars dispersed in the first molding layer.

14. The semiconductor package of claim 12, wherein an elastic modulus of the second molding layer is larger than an elastic modulus of the first molding layer.

15. The semiconductor package of claim 12, further comprising a metal layer, a metal nitride layer, or a ceramic layer on the second molding layer.

16. The semiconductor package of claim 15,
wherein the metal layer comprises copper (Cu), titanium (Ti), or stainless steel,
the metal nitride layer includes titanium nitride (TiN), and
the ceramic layer includes silicon nitride (SiN).

17. The semiconductor package of claim 12, wherein a thickness of the second molding layer is about 1 micrometer to about 500 micrometers.

18. The semiconductor package of claim 12, wherein the second molding layer is in contact with the first molding layer.

19. The semiconductor package of claim 12, wherein the second molding layer extends onto second surfaces of the first molding layer and is provided on the second surfaces of the first molding layer, and
wherein the second surfaces of the first molding layer are perpendicular to the first surface of the first molding layer.

20. A semiconductor package comprising:
a package substrate;
a semiconductor chip on the package substrate;
a molding layer on the semiconductor chip on the package substrate;
a protective layer on a surface of the molding layer; and
one or more connection terminals provided on a surface of the package substrate,
wherein the molding layer comprises one or more thermal conductive members dispersed in the molding layer,
wherein a thickness of the protective layer is less than a thickness of the molding layer, and
wherein the protective layer comprises:
an insulating layer formed of a molding member, and
at least one of a metal layer, a metal nitride layer, or a ceramic layer stacked on the insulating layer.
